(19) United States
(12) Patent Application Publication
(10) Pub. No.: US 2013/0061842 A1
(43) Pub. Date: Mar. 14, 2013

(54) SINGLE-LAYERED WINDING OF SAWING WIRE WITH FIXEDLY BONDED ABRASIVE GRAIN FOR WIRE SAWS FOR SLICING WAFERS FROM A WORKPIECE

(71) Applicants: Joachim Junge, Burghausen (DE); Joerg Moser, Unterneukirchen (DE)

(72) Inventors: Joachim Junge, Burghausen (DE); Joerg Moser, Unterneukirchen (DE)

(73) Assignee: SILTRONIC AG, Munich (DE)

(21) Appl. No.: 13/594,897

(22) Filed: Aug. 27, 2012

(30) Foreign Application Priority Data
Sep. 8, 2011 (DE) 10 2011 082 366.2

(51) Int. Cl. H01L 21/304

(52) U.S. Cl. 125/21

(57) ABSTRACT

Wire spools used for multiple wire saws for slicing one or more wafers from a workpiece composed of semiconductor material using a wire web including parallel wire sections coated with bonded abrasive grain. The wire spools include a first wire spool configured as a dispensing spool and a second wire spool configured as a receiver spool. A sawing wire coated with bonded abrasive grain runs from the first wire spool via at least one deflection roll to the wire web and from the wire web via at least one deflection roll to the second wire spool. The sawing wire enters into guide grooves of the deflection rolls at an alignment angle α1 and exits the guide grooves of the deflection rolls at an alignment angle α2. The sawing wire has a single layer winding on each of the first and second wire spools.

### CROSS REFERENCE TO RELATED APPLICATIONS

This application claims priority to German Patent Application No. DE 10 2011 082 366.2, filed Sep. 8, 2011, which is hereby incorporated by reference herein in its entirety.

### FIELD

The invention relates to wire spools for a wire saw for slicing wafers from a workpiece, wherein the sawing wire coated with fixedly bonded abrasive grain is wound on the wire spool in a single-layered fashion. The invention is applicable both to single-cut wire saws and to multiple wire saws.

### BACKGROUND

For electronics, microelectronics and microelectromechanics, semiconductor wafers with extreme requirements made of global and local flatness, single-side-referenced local flatness (nanotopology), roughness and cleanness are required as starting materials (substrates). Semiconductor wafers are wafers composed of semiconductor materials, more particularly compound semiconductors such as gallium arsenide and predominantly elemental semiconductors such as silicon and occasionally germanium. In accordance with the prior art, semiconductor wafers are produced in a multiplicity of successive process steps, wherein, in the first step, by way of example, a single crystal (rod) composed of semiconductor material is pulled by means of the Czoehralski method or a polycrystalline block composed of semiconductor material is cast, and, in a further step, the resulting circular-cylindrical or block-shaped workpiece composed of semiconductor material (“ingot”) is separated into individual semiconductor wafers by means of wire saws.

In this case, a distinction is made between single-cut wire saws and multiple wire saws, designated hereinafter MW saws (MW=multiple wire). MW saws are used, in particular, when a workpiece, for example a rod composed of semiconductor material, is intended to be sawn into a multiplicity of wafers in one work step.

U.S. Pat. No. 5,771,876 describes the functional principle of a wire saw suitable for producing semiconductor wafers. The essential components of these wire saws include a machine frame, a feed device and a sawing tool consisting of a web (“wire web”) composed of parallel wire sections.

An MW saw is described in EP 990 498 A1, for example. In this case, a long sawing wire coated with bonded abrasive grain runs spirally over wire spools and forms one or more wire webs.

In general, the wire web is formed from a multiplicity of parallel wire sections which are clamped between at least two wire guide rolls, wherein the wire guide rolls are mounted in rotatable fashion and at least one of them is driven. The wire guide rolls are usually provided with a coating, for example polyurethane. Moreover, they have a multiplicity of grooves through which the sawing wire is guided and whereby the wire web of the wire saw is formed. A wire guide roll optimized with regard to surface coating and groove geometry is described in DE 10 2007 019 566 A1.

The longitudinal axes of the wire guide rolls are generally oriented perpendicularly to the sawing wire in the wire web.

The wire sections of the wire web can belong to a single, finite wire that is guided spirally around the roll system and is unwound from a supply roll (dispenser spool) onto a receiving roll (receiver spool). The patent specification U.S. Pat. No. 4,655,191, by contrast, describes an MW saw wherein a multiplicity of finite wires are provided and each wire section of the wire web is assigned to one of said wires. EP 522 542 A1 also describes an MW saw wherein a multiplicity of continuous wire loops run around the roll system.

The production of wafers composed of semiconductor material makes particularly stringent requirements of the precision of the slicing process. For this purpose, it is important that the multiplicity of grooves on the wire guide roll run exactly parallel and the grooves and the sawing wire lie in one line (alignment). As a result of wear of the wire guide rolls, an alignment error, can occur, i.e. the groove of the wire guide roll and the wire lying in said groove no longer lie on a straight line. This can lead to damage, for example scoring, of the surfaces of the sliced semiconductor wafers. DE 102 20 640 A1 describes a method for monitoring and, if appropriate, correcting the alignment of the sawing wire with respect to the grooves of the wire guide rolls.

The sawing wire can be coated with an abrasive coating. When use is made of wire saws having sawing wire without fixedly bonded abrasive grain, abrasive grain is supplied in the form of a slurry (“abrasive slurry”, “sawing slurry”) during the slicing process.

Sawing wire with fixedly bonded abrasive grain has particles, e.g. diamond, having an abrasive action which are fixedly bonded on the wire surface and which foster the penetration of a workpiece.

In the course of the slicing process, the workpiece penetrates through the wire web. The penetration of the wire web is brought about by means of a feed device that guides the workpiece toward the wire web, the wire web toward the workpiece or the workpiece and the wire web toward one another, wherein the wire web moves relative to the workpiece.

In the course of the slicing process, the sawing wire is moved in one direction on average over time, wherein the direction of movement of the sawing wire does not have to remain the same, but can also be changed at time intervals (oscillating method).

The wire web is supplied with sawing wire by rotating wire spools both on the inlet side and ort the outlet side of the workpiece. The sawing wire is unwound from one wire spool (dispensing spool) and wound up on the other wire spool (receiver spool), wherein the sawing wire remains uniformly tensioned in the wire web. The actual drive is effected via one or more wire guide rolls.

Depending on the direction of rotation, one wire spool can dispense or receive the wire and therefore buffer the wire not currently cutting into the workpiece to be sawn. In the case of an oscillating sawing process, dispenser and receiver spools respectively swap their function when the wire feed direction is changed. In the case of a continuous sawing process, dispenser and receiver spools remain in their respective function.

In accordance with the prior art, the sawing wires are wound on the wire spools of the MW saws in a multilayered fashion. Particularly in the case of sawing wires coated with a bonded abrasive grain, the contacts and thus the relative movements between the surfaces of the sawing wire turns on the wire spools lead to additional premature wear of the sawing wire. As a result of the wear, the sawing wire occupied by abrasive grain loses cutting capacity and the wire sections of the wire web acquire degrees of wear of different magnitudes. This leads to a nonuniform sawing result.

Furthermore, during operation of the MW saws, likewise owing to the wear mentioned above, wire cracks occur more frequently than in the case of comparable wire saws wherein a smooth sawing wire in combination with loose abrasive grain supplied in the form of a slurry is used.

A reduced wear of a sawing wire coated with bonded abrasive grain can be achieved by single-layered winding on the dispenser spool and the receiver spool.

The single-layered winding of the sawing wire is described for single-cut saws in U.S. Pat. No. 4,484,502A, for example. The sawing wire is buffered on two spools provided with an external thread. The drive of these threaded spools sets the wire in motion, wherein, in a manner governed by drive and/or thread, the sawing wire necessarily moves in an axial direction with respect to the threaded spools. In order to compensate for this axial movement, the pair of spools is laid counter to the axial displacement by means of a movement unit. The single-layered winding technology described in U.S. Pat. No. 4,484,502A for single-cut saws requires very few deflection rolls that are likewise movable in an axial direction. However, on account of the axial movement of the sawing wire, this single-layered winding technology cannot be applied to an MW saw in accordance with the prior art. Furthermore, in the case of the single-layered winding, there is too little sawing wire available on the dispensing spool for the sawing of rods composed of semiconductor material.

### SUMMARY

In an embodiment, the present invention provides wire spools that are used for multiple wire saws for slicing one or more wafers from a workpiece composed of semiconductor material using a wire web including parallel wire sections coated with bonded abrasive grain The wire spools include a first wire spool configured as a dispensing spool and a second wire spool configured as a receiver spool. A sawing wire coated with bonded abrasive grain runs from the first wire spool via at least one deflection roll to the wire web and from the wire web via at least one deflection roll to the second wire spool. The sawing wire enters into guide grooves of the deflection rolls at an alignment angle α1 and exits the guide grooves of the deflection rolls at an alignment angle α2. The sawing wire has a single layer winding on each of the first and second wire spools.

### BRIEF DESCRIPTION OF THE DRAWINGS

Exemplary embodiments of the present invention are described more detail below with reference to the drawings, in which:

FIGS. 1a and 1b show dispensing wire extending from wire spools via deflection rolls;

FIG. 2 shows a construction of an MW saw; and

FIG. 3 shows a laying unit.

### DETAILED DESCRIPTION

In an embodiment, the present invention provides an improved method for slicing a multiplicity of wafers from a workpiece composed of semiconductor material with the aid of an MW saw having sawing wire with fixedly bonded abrasives, wherein the premature wear of the sawing wire is reduced and enough sawing wire is available for an economically viable sawing process.

This is achieved by means of wire spools for multiple wire saws for slicing one or more wafers from a workpiece composed of semiconductor material by means of a wire web consisting of parallel wire sections coated with bonded abrasive grain, wherein, from the first wire spool, serving as a dispenser spool, sawing wire coated with bonded abrasive grain runs via at least one deflection roll to the wire web, the sawing wire coated with bonded abrasive grain runs from the wire web via at least one deflection roll to the second wire spool, which serves as a receiver spool, the sawing wire enters at an alignment angle α1 into the guide grooves of the deflection rolls and leaves the guide grooves of the deflection rolls at an alignment angle α2, wherein the winding of the sawing wire on each of the two wire spools is single-layered.

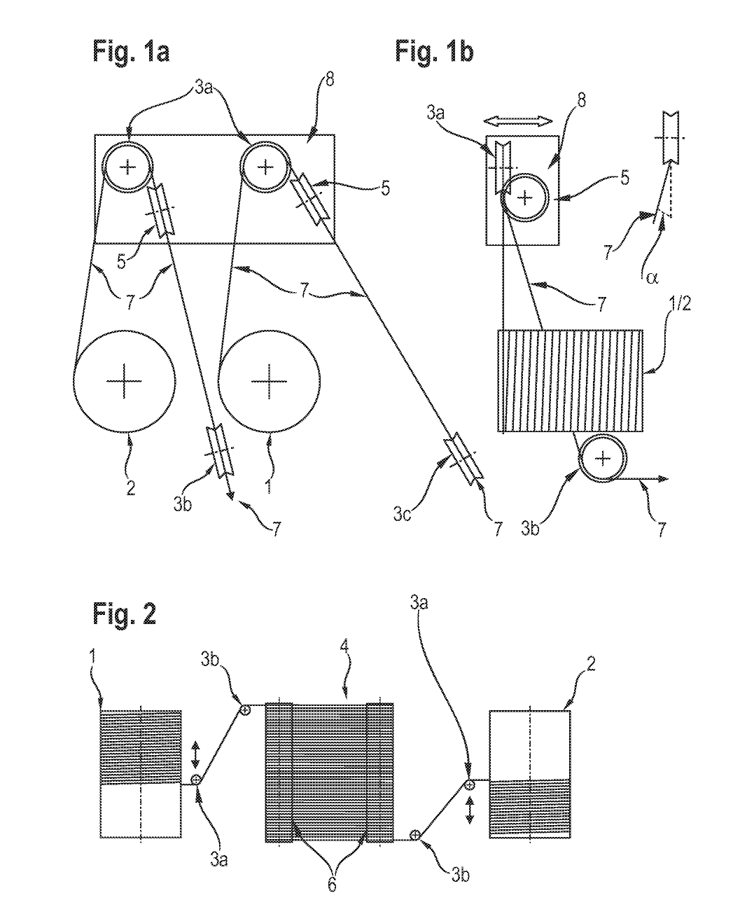

FIG. 1 shows an example a wire laying method for an MW saw. The arrows on the sawing wire 7 that are depicted in FIG. 1 schematically indicate whether the wire runs in the direction of the wire web, which is not depicted for reasons of clarity, or comes from the wire web.

FIG. 1a shows how the sawing wire 7 unwound from the dispensing spool 2 is guided via the two deflection rolls 3a and 5, which are movable parallel to the rotation axes (longitudinal axes) of the dispensing spool 2 and of the receiver spool 1 and whose rotation axes are at an angle of 90° with respect to one another and which are fixed on a common receptacle plate 8, to a stationary (non-movable) deflection roll 3b, which directs the sawing wire 7 into the wire web. When the sawing wire 7 exits from the wire web, the sawing wire 7 is wound onto the receiver spool 1 in multilayered fashion via two further movable deflection rolls 3a and 5, whose rotation axes are at an angle of 90° with respect to one another and which are likewise fixed on the common receptacle plate 8.

FIG. 1b shows by way of example how the deflection rolls 3a and 5, which are movable parallel to the rotation axis of the dispensing spool 2 and whose rotation axes are at an angle of 90° with respect to one another and which are fixed on a common receptacle plate 8, are movable parallel to the rotation axis of the dispensing spool 2 in order that the alignment angle α1 at which sawing wire 7 enters into the guide groove of the deflection roll 3a is kept minimal. Given an ideal alignment angle of 0°, the sawing wire enters into and exits from the guide groove of the deflection roll exactly perpendicularly. After the sawing wire 7 has exited from the guide groove of the deflection roll 3a, the sawing wire 7 enters into the guide groove of the deflection roll 5 and from there is guided past the dispensing spool 2 via the stationary deflection roll 3b to the wire web.

FIG. 2 schematically shows the construction of an MW saw, in which, according to the invention, the sawing wire 7 is wound on the dispensing spool and receiver spool, respectively, in single-layered fashion. For better clarity, only one of the two movable deflection rolls is depicted in each case. Here the dispensing spool 2 is tilled with sawing wire 7 to the extent of 60% and passes the sawing wire 7 to the wire web 4 whilst executing a rotational movement about the longitudinal axis, via the movable deflection roll 5, which is moved parallel to the longitudinal axis of the dispensing spool 2, and via the stationary deflection roll 3b and the wire guide rolls 6. The sawing wire 7 exiting from the wire web 4 via the opposite wire guide roll 6 is wound onto the receiver spool 1 via the stationary deflection roll 3b and the movable deflection roll 5 in a single-layered fashion, whilst executing a rotational movement about the longitudinal axis.

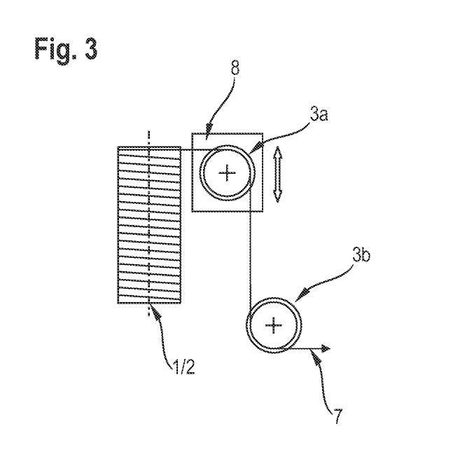

FIG. 3 shows a particularly preferred laying unit for wrapping from a multiply wound dispensing spool onto a receiver spool that is to be wound in single-layered fashion and the subsequent oscillating operation, since here the problem of a varying alignment angle α (α is used hereinafter in summary for the alignment angles α1 and α2) is omitted. The sawing wire 7 is guided via a deflection roll 5, which is movable parallel to the longitudinal axis of the dispensing spool 2 and receiver spool 1, respectively, and is fixed on a receptacle plate 8 and whose rotation axis is perpendicular to the longitudinal axis of the dispensing spool 2 and receiver spool 1, respectively. In this way, the alignment angle α between the groove plane of the deflection roll 5 and the sawing wire 7 coming from the dispensing spool 2 or running to the receiver spool 1 does not vary and can therefore be set fixedly to a minimum value. From the deflection roll 5, the sawing wire 7 is guided to the wire guide rolls of the wire web via the stationary deflection roll 3b, whose rotation axis is perpendicular to the longitudinal axis of the dispensing spool 2 and receiver spool 1, respectively, and parallel to the longitudinal axis of the deflection roll 5.

The wire spools according to the invention can be applied both to an MW saw designed for the use of a sawing wire with bonded abrasive grain, and to a slurry MW saw such as the HCT DS420-E12 from the manufacturer Applied Materials Switzerland SA, for example, which is designed for the use of a sawing wire without bonded abrasive grain. This slurry MW saw can be converted for operation by means of diamond wire in accordance with EP 0 990 498 A1

In accordance with the prior art, the sawing wires in a wire saw are wound on wire spools in multilayered fashion. A wire spool for a wire saw is a circular-cylindrical object having an outer convex lateral surface, around which the sawing wire is wound in single-layered or multilayered fashion, and an inner core. The inner core comprises the two side surfaces of the spool and is enveloped by the lateral surface parallel to the longitudinal axis of the spool. The devices for suspending the spool in the wire saw are situated at the side surfaces of the spool core.

Since, in the case of the single-layered winding, the amount of sawing wire that can be wound onto a spool having a defined length and a defined diameter is less than that in the case of the multilayered winding, a spool maximized both in its external diameter and in its length is used for the device according to the invention.

The single-layered winding of the dispensing and receiver spools is effected with the aid of an adapted laying device, which is described further below.

For the implementation of the invention, the wire web of an MW saw is equipped from a commercially available dispensing spool with sawing wire wound in multilayered fashion and coated with a bonded abrasive gain. Afterward, instead of the standard spool on the “receiver side”, a receiver spool maximized both in its external diameter and in its length with regard to the volume to be machined (length and cross section of the workpiece) is incorporated.

The take-up capacity of the spool is determined, in the case of single-layered, contactless winding, firstly by the length and the diameter of the spool and secondly by the diameter and the winding pitch of the sawing wire.

Preferably, a spool according to the invention is used which, in the case of single-layered winding, can take up a sawing wire coated with fixed abrasive grain and having a length of at least 1 km.

By way of example, given a diameter of the spools according to the invention of 378 mm and a length of 350 mm, given a set winding pitch of the sawing wire of 0.3 mm, a total of 1230 in of sawing wire having a diameter of 0.12 mm can be stored on the spools according to the invention.

Particularly preferably, a spool according to the invention is used which, in the case of single-layered winding, can take up a sawing wire coated with fixed abrasive grain and having a length of at least 10 km.

Since the length of the spools used has no influence on the size of the wire web in a wire saw, the spools according to the invention can be incorporated, in principle, in any MW saw in accordance with the prior art.

The receiver spool according to the invention is filled by means of wire feed via the wire web with the aid of a laying device in single-layered fashion with a defined wire pitch with the sawing wire over the entire axial length of the spool. For this purpose, the sawing wire coated with fixedly bonded abrasive grain from a commercially available multiply wound supplier spool is used.

Both the winding pitch and the respective position of a wire section are unknown on a commercially available multiply wound supplier spool, such that the alignment angle α at which the sawing wire impinges on the first deflection roll—positioned fixedly with respect to the supplier spool—of a laying unit in accordance with the prior art is not controllable.

If the sawing wire impinges on the fixedly positioned deflection roll at an excessively large alignment angle α, this leads to premature wear of the sawing wire as early as in the course of wrapping.

In order to solve this problem, preferably, for the initial wrapping onto the spools according to an embodiment of the invention, use is additionally made of a toiler having a smooth, cylindrical surface instead of a laying device. The mounting location of the roller is chosen so as to result in the greatest possible path for the sawing wire between dispensing spool and the first deflection roll. The cylindrical surface of the roller allows the wire to be oriented in an axial direction of the roller freely on the roller and thus brings about a reduction of the alignment angle α of the sawing wire at which the sawing wire impinges on the guide groove of the deflection roll.

Particularly preferably, for the initial wrapping from a commercially available supplier spool wound in multilayered fashion onto the wire spool, the laying unit in accordance with FIG. 3 is used. The laying unit according to FIG. 3 does not have the problem of the alignment angle α. By virtue of the deflection roll 5 which is movable parallel to the rotation axis of the dispensing spool 2 (during initial wrapping) and is fixed on a receptacle plate 8 and whose rotation axis is perpendicular to the rotation axis of the dispensing spool 2, the free wire length between wire spool and deflection roll is always minimal.

The wire laying is chosen such that it begins during the initial filling of the receiver spool 1 firstly at an end side and positions the wire with each turn toward the opposite end side with a defined wire pitch. The individual sawing wire turns on the spool do not touch one another.

Preferably, the single-layered winding of the sawing wire coated with fixedly bonded abrasive grain on the receiver spool is effected with a wire pitch corresponding to twice the value of the wire diameter.

If the receiver spool is filled (wound) in single-layered fashion, the wire is separated at the commercially available supplier spool (dispensing spool) and the latter is removed from the wire saw, instead of the commercially available supplier spool, a wire spool identical with regard to the length and the diameter of the receiver spool according to the invention is incorporated, which now serves as receiver spool. The receiver spool previously wound in single-layered fashion according to the invention now serves as dispensing spool. The sawing wire coated with bonded abrasive grain is fixed to the receiver spool by means of at least one screw.

The abrasives fixedly bonded on the surface of the sawing wire, such as diamond fragments, for example, bring about high friction between the sawing wire 7 and the deflection rolls 3a, 3b and 5. The high friction between sawing wire 7 and wire guide rolls 6 and the fact that the individual grooves in the wire guide rolls 6 are situated fixedly with respect to one another and are not individually mounted have the effect that the high tensile stress remains in the sawing web. Within the last turn of the sawing web, the wire stress between the wire guide roll 6 and the dispensing spool 2 and the receiver spool 1, respectively, decreases if the stress is reduced to a predetermined value during unwinding and during winding-up, respectively. It is therefore possible to realize a lower tensile stress between the deflection rolls 3a, 3b and 5 and the dispensing spool 2 and receiver spool 1, respectively, and a higher tensile stress in the wire web 4. A corresponding method for reducing the tensile stress of the sawing wire before winding-up onto the receiver spool for a wire saw in oscillating operation is disclosed in DE 198 28 420 A1

In an MW saw in accordance with the prior art, the saw is driven by the wire guide rolls 6, which in each case rotate about their longitudinal axis running parallel to the rotation axes of the dispensing spool 2 and receiver spool 1, respectively. The dispensing spool 2 and receiver spool 1 are likewise driven and rotate at a variable speed about their longitudinal axes, such that defined tensile stresses are present between the dispensing spool 2 and receiver spool 1, respectively, and the deflection rolls 3a, 3b and 5, which can differ from the tensile stress in the wire web 4.

The dispensing spool 2 and receiver spool 1 according to the invention are torque-controlled during operation of the MW saw in accordance with the prior art.

In accordance with DE 198 28 420 A1, the tensile stress in the wire web is set by the difference between the torques of dispensing spool 2 and wire guide roll 6. If the torque of the spool (receiver spool 1) currently being wound up is reduced, the tensile stress of the sawing wire 7 running onto the receiver spool 1 decreases, wherein the tensile stress in the wire web 4 is maintained. If the receiver spool 1 changes its function and becomes the dispensing spool 2, high torque is again employed, such that the sawing wire 7 is guided onto the wire web 4 with high tensile stress. The difference in torques between wire web 4 and receiver spool 1 is insignificant for tensile stress in the wire web 4 and only determines the tensile stress of the sawing wire 7 running onto the receiver spool 1.

The tensile stress on the dispensing spool 2 and the receiver spool 1, respectively, that is reduced when using the wire spools according to the invention by comparison with the wire web 4 minimizes the tensile forces acting on the spools. This makes it possible to use softer materials as spool material without influencing the dimensional stability of the spool.

Preferably, the winding of the dispensing spool 2 and receiver spool 1, respectively, is effected with a tensile stress of 1 to 5 newtons.

The lateral surface of the spool according to the invention is formed from a soft material. Polyurethane is preferably used as material. Likewise preferred materials are elastomers such as rubber/carbon mixtures, silicones or PVC. Aluminum is also preferred.

The inner core of the spool is preferably produced from steel or high-grade steel,

Preferably, the lateral surface of the spool according to the invention is smooth. Preference is likewise given to a lateral surface which has a profiled notch running continuously helically around the lateral surface (thread structure) and in the case of which the sawing wire has been wound or is wound along or in the notch around the lateral surface.

In the wire web 4, a tensile stress of 10 to 30 newtons is preferably set when using the spools according to the invention. Particularly preferably, a tensile stress of 25 to 30 newtons is set in the wire web 4.

During the sawing process, according to the invention, the sawing wire 7 coated with fixedly bonded abrasive grains is likewise wound up in single-layered fashion again on the receiver spool 1. In order to be able to wind up the sawing wire 7 with a defined spacing in single-layered fashion on the receiver spool 1, it has to be laid with a defined spacing (pitch) in an axial direction along the receiver spool 1, beginning at one of the two end sides. For this purpose, the movable deflection roll 3a, which guides the sawing wire directly onto the receiver spool 1, is moved with each revolution of the receiver spool 1 parallel to the rotation axis of the receiver spool 1 by a specific distance uniformly in the winding direction, such that the movable deflection roll 3a is always aligned with the entry position of the sawing wire on the receiver spool and the alignment angle α is minimal.

Preferably, the distance covered by the movable deflection roll 3a parallel to the rotation axis of the receiver spool 1 with each revolution of the receiver spool 1 corresponds to twice the value of the diameter of the sawing wire 7.

During the transporting of the sawing wire from the position of the deflection roll 3a that is movable parallel to the respective rotation axis of the wire spools (dispensing and receiver spool, respectively) to the nearest stationary deflection roll 3b, which deflects the sawing wire 7 to the wire web 4, a minimum angle (alignment angle α) between the wire direction and the groove planes of both deflection rolls must not be exceeded, in order to minimize the deflection roll wear and the risk of sawing wire cracking.

Preferably, the value for the alignment angle α lies in the range of 0-2°. Particularly preferably, the alignment angle is α≦1°.

If the laying unit reaches the end of the spool (the other end side), the wire spool automatically changes its function, i.e. the receiver spool 1 becomes the dispensing spool 2, and vice versa. The corresponding positions are set in the control software of the wire saw.

Preferably, in the device according to the invention, the rotation axes of the dispensing and receiver spoofs and of the movable deflection roll 3a are parallel to one another (FIG. 2). In this embodiment, by means of a second movable deflection roll 5, the rotation axis of which is tilted by 90° relative to the rotation axis of the deflection roll 3a and which is fixed together with the deflection roll 3a on a guide plate 8, the sawing wire 7 is guided to the nearest stationary deflection 3b. In this case, the movability of the deflection rolls 3a and 5 is ensured by the guide plate 8, which is movable parallel to the respective rotation axis of the wire rolls and on which the deflection rolls 3a and 5 are fixed.

In a second preferred embodiment of the device according to the invention, the rotation axes of the dispensing spool 2 and of the receiver spool 1 and of the movable deflection roll 5 are perpendicular to one another (FIG. 3). In this ease, the movability of the deflection roll 5 is ensured by the guide plate 8, which is movable parallel to the respective rotation axis of the wire rolls and on which the deflection roll 5 is fixed. With the laying unit in accordance with FIG. 3, the alignment angle α between the groove plane of the deflection roll 5 and the sawing wire 7 conning from the dispensing spool 2 and running to the receiver spool 1 does not vary and can therefore be fixedly set to a minimum value. The sawing wire 7 is guided directly from the deflection roll 5 to the nearest stationary deflection roll 3b.

Preferably, in another embodiment of the device according to the invention, the alignment angle α lies in the range of 0 to 2°. Particularly preferably, the alignment angle is α≦1°.

The sawing wire 7 emerging from the wire web 4 is directed via one or more stationary deflection rolls 3b in accordance with FIG. 3 to the movable deflection roll 5 fixed on a receptacle plate 8. Via the movable deflection roll 5, which is guided parallel to the rotation axis of the receiver spool 1 and whose rotation axis is perpendicular to the rotation axis of the receiver spool 1, the emerging wire 7 is wound on the rotating receiver spool 1 in single-layered fashion by means of a device in accordance with FIG. 3.

In one preferred embodiment of the device according to the invention, a common laying device is used for the dispensing spool 2 and receiver spool 1. The two movable deflection rolls 5, which determine the laying position of the sawing wire 7 on the dispensing spool 2 and the receiver spool 1, are operated by a common drive. For this purpose, the bearings of the two deflection rolls are mounted on a common receptacle plate 8. The position of said receptacle plate relative to the dispensing spool 2 and the receiver spool 1 is moved by the laying drive parallel to the rotation axis of the dispensing and receiving spools.

In a likewise preferred embodiment of the device according to the invention, separate laying devices are used for dispensing spool 1 and receiver spool 2.

In this embodiment, the dispensing spool 2 and the receiver spool 1 are operated by a respective dedicated laying unit. The rotation axes of the two wire spools are aligned parallel and are respectively perpendicular to the rotation axes of the movable deflection rolls 5, in the ease of the dispensing spool function, the optimum laying position is determined in a sensor-based fashion, such that the sawing wire leaving the dispensing spool always enters at a minimum alignment angle α1 into the guide groove of the nearest deflection roll. In the case of the receiver spool function, the laying position is determined in such a way that the sawing wire 7 is wound onto the receiver spool 1 in single-layered fashion.

The use of the sawing wire 7 gives rise to torsional and bending stresses which have the effect that the sawing wire 7 can no longer be wound exactly straight onto the receiver spool 1. Therefore, the wire pitch in the case of single-layered winding is chosen such that, despite the stresses arising as a result of the use of the sawing wire 7, superimposition or touching of wire sections on the receiver spool 1 is precluded.

Preferably, the sawing wire 7 is wound on the receiver spool 1 in single-layered fashion with a wire pitch corresponding to 1.5 times the value of the wire diameter. Preference is likewise given to winding the sawing wire in single-layered fashion with a wire pitch corresponding to 2.5 times the value of the wire diameter. Particularly preferably, the sawing wire is wound in single-layered fashion with a wire pitch corresponding to double the value of the wire diameter.

The wire spools wound in single-layered fashion according to the invention can also be employed in the case of an oscillating mode of operation of the MW saw. In the case of oscillating operation of the MW saw, the dispensing spool 2 and the receiver spool 1 alternately swap their function depending on the process parameters.

The wire spools wound in single-layered fashion according to the invention also enable the multiple use of the wire spools and lead to reduced wear of the sawing wire coated with fixedly bonded abrasives. These advantages increase the economic viability of MW saws.

While the invention has been particularly shown and described with reference to preferred embodiments thereof, it will be understood by those skilled in the art that various changes in form and details may be made therein without departing from the spirit and scope of the invention.

1: Wire spools for multiple wire saws for slicing one or more wafers from a workpiece composed of semiconductor material using a wire web including parallel wire sections coated with bonded abrasive grain, comprising:
a first wire spool configured as a dispensing spool;
a second wire spool configured as a receiver spool; and
sawing wire coated with bonded abrasive grain, the sawing wire running from the first wire spool via at least one deflection roll to the wire web and from the wire web via at least one deflection roll to the second wire spool, the sawing wire entering into guide grooves of the deflection rolls at an alignment angle α1 and exiting the guide grooves of the deflection rolls at an alignment angle α2, the sawing wire having a single layer winding on each of the first and second wire spools.

2: The wire spools as claimed in claim 1, wherein individual wire turns on the wire spools do not touch one another.

3: The wire spools as claimed in claim 1, wherein the sawing wire is laid in an axial direction of the wire spools using a common laying unit.

4: The wire spools as claimed in claim 1, wherein the sawing wire is laid in an axial direction of the wire spools using two individual laying units.

5: The wire spools as claimed in claim 1, wherein a lateral surface of the wire spools includes an elastomer.

6: The wire spools as claimed in claim 5, wherein the elastomer is produced from the group consisting of polyurethane, a rubber/carbon mixture, silicone and PVC.

7: The wire spools as claimed in claim 1, wherein a lateral surface of the wire spools includes aluminum.

8: The wire spools as claimed in claim 1, wherein the wire situated on the wire spools has a lower tensile stress than the wire situated in the web.

9: The wire spools as claimed in claim 8, wherein the wire situated on the wire spools has a tensile stress of 1 to 5 newtons.

10: The wire spools as claimed in claim 8, wherein the wire web has a tensile stress of 10 to 30 newtons.

11: The wire spools as claimed in claim 1, wherein the alignment angles α1 and α2 are each in a range of between 0 and 2°.
